(19) United States
(12) Patent Application Publication
(10) Pub. No.: US 2015/0371889 A1
(43) Pub. Date: Dec. 24, 2015

(54) METHODS FOR SHALLOW TRENCH ISOLATION FORMATION IN A SILICON GERMANIUM LAYER

(71) Applicant: APPLIED MATERIALS, INC., Santa Clara, CA (US)

(72) Inventors: HUN SANG KIM, San Ramon, CA (US); WONMO AHN, Fremont, CA (US); SHINICHI KOSEKI, Palo Alto, CA (US); JINHAN CHOI, Frisco, TX (US); SEAN KANG, San Ramon, CA (US)

(21) Appl. No.: 14/310,607

(22) Filed: Jun. 20, 2014

(51) Int. Cl. H01L 21/76; H01L 21/308; H01L 21/3065

(52) U.S. Cl. CPC H01L 21/76; H01L 21/3065; H01L 21/308

(57) ABSTRACT

Methods for processing a substrate include (a) providing a substrate comprising a silicon germanium layer and a patterned mask layer atop the silicon germanium layer to define a feature in the silicon germanium layer; (b) exposing the substrate to a first plasma formed from a first process gas to etch a feature into the silicon germanium layer; (c) subsequently exposing the substrate to a second plasma formed from a second process gas to form an oxide layer on a sidewall and a bottom of the feature; (d) exposing the substrate to a third plasma formed from a third process gas to etch the oxide layer from the bottom of the feature; and (e) repeating (b)-(d) to form the feature in the first layer to a desired depth, wherein the first process gas, the second process gas and the third process gas are not the same.

### FIELD

Embodiments of the present invention generally relate to forming features in a silicon germanium layer on a substrate.

### BACKGROUND

In electronic device fabrication, substrates often have shallow trench isolation (STI) structures used, for example, to isolate different devices formed on the semiconductor wafer. STI structures are often formed in a silicon germanium layer. One challenge of fabricating, or etching, shallow trench isolation (STI) structures in a silicon germanium layer is that the silicon germanium layer is easily damaged during STI formation.

Accordingly, the inventors have provided improved methods of forming a STI feature in a silicon germanium layer.

### SUMMARY

Embodiments of methods for forming a STI feature in a silicon germanium layer are described herein. In some embodiments, a method of processing a substrate, includes (a) providing a substrate to a substrate support in a process chamber, wherein the substrate comprises a silicon germanium (SiGe) layer and a patterned mask layer atop the silicon germanium layer to define a feature in the silicon germanium layer; (b) exposing the substrate to a first plasma formed from a first process gas to etch a feature into the silicon germanium layer; (c) subsequently exposing the substrate to a second plasma formed from a second process gas to form an oxide layer on a sidewall and a bottom of the feature; (d) exposing the substrate to a third plasma formed from a third process gas to etch the oxide layer from the bottom of the feature; and (e) repeating (b)-(d) to form the feature in the first layer to a desired depth, wherein the first process gas, the second process gas and the third process gas are not the same.

In some embodiments, a method of forming features in a silicon germanium (SiGe) layer of a substrate having a patterned layer disposed atop the silicon germanium layer to define one or more features to be etched into the silicon germanium layer, wherein the substrate is disposed on a substrate support in a processing volume of a process chamber, includes: (a) exposing the substrate to a first plasma formed from a chlorine containing gas to etch a feature into the silicon germanium layer, wherein the feature comprises sidewalls and a bottom; (b) subsequently exposing the substrate to a second plasma formed from an oxygen containing gas to form an oxide layer on the sidewalls and bottom of the feature; (c) subsequently exposing the substrate to a third plasma formed from a fluorine containing gas to etch the oxide layer from the bottom of the feature; (d) applying a bias power to the substrate of about 30 watts to about 400 watts during (a) and (c) and at a frequency of about 2 MHz; and (e) repeating (a)-(d) to form the feature in the first layer to a desired depth.

In some embodiments, a computer readable medium is provided having instructions stored thereon that, when executed, causes a process chamber to perform a method for processing a substrate. The method may include any of the methods disclosed herein.

Other and further embodiments of the present invention are described below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for processing a substrate in accordance with some embodiments of the present invention.

FIGS. 2A-2E respectively depict the stages of fabrication of forming a shallow trench isolation structure in a silicon germanium layer accordance with some embodiments of the present invention.

FIG. 3 depicts a schematic side view of a process chamber suitable for performing portions of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods for processing a substrate that may advantageously provide improved shallow trench isolation (STI) structures in silicon germanium layer. The inventors have observed that simply etching a feature in the silicon germanium layer to a desired depth undesirably results in damage to the sidewalls of the feature. The inventors have observed that etching the feature by looping a cycle of etching, oxidizing, and oxide layer breakthrough as described below can reduce or eliminate damage to the sidewall of the feature.

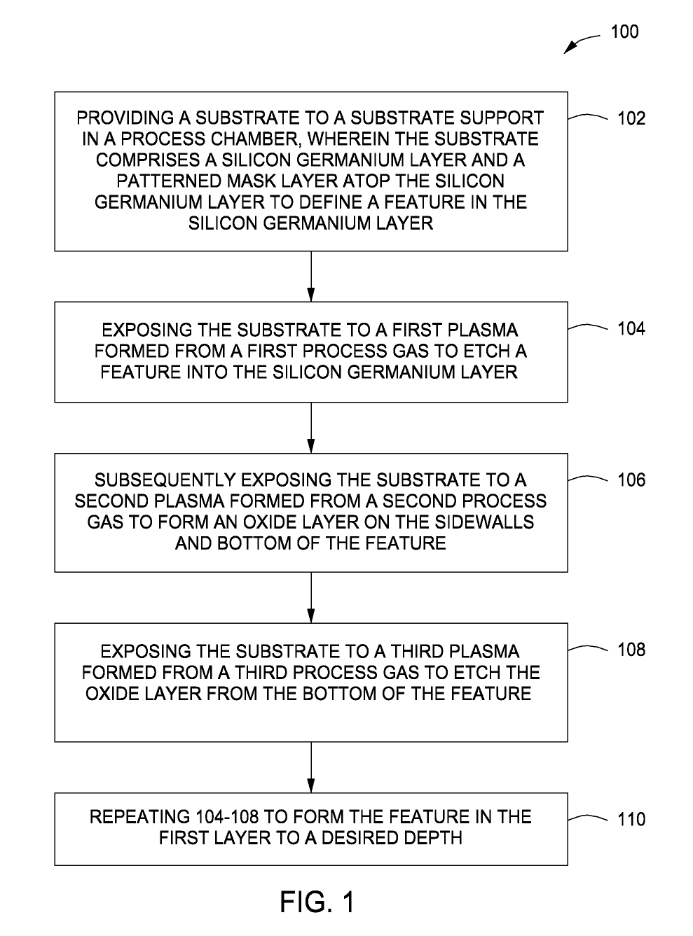

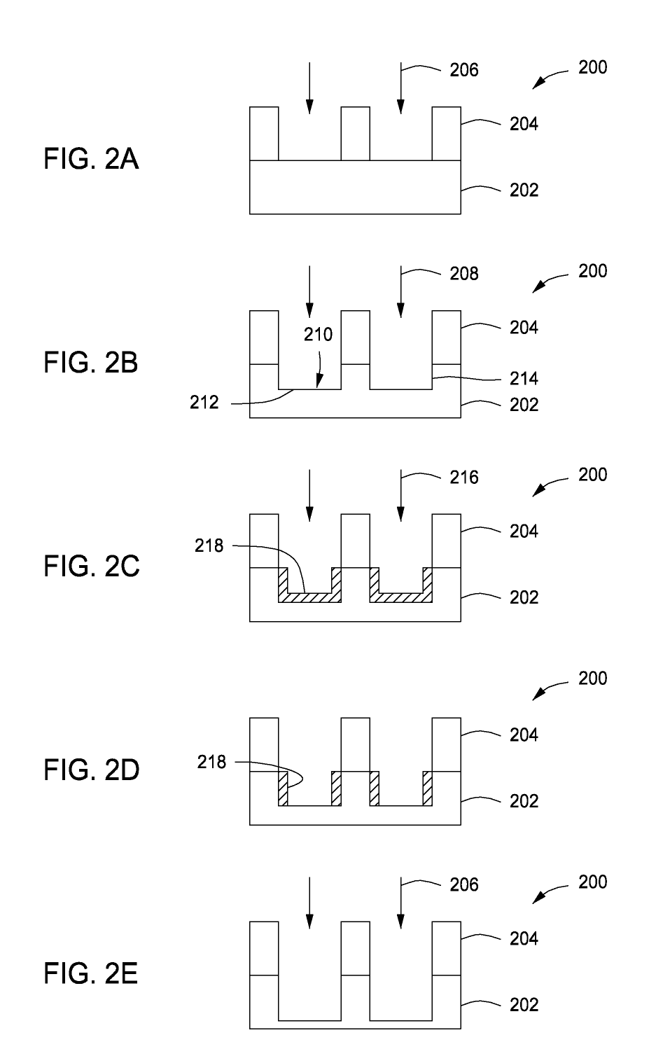

FIG. 1 is a flow diagram of a method 100 for etching a shallow trench isolation structure in a silicon germanium layer in accordance with some embodiments of the present invention. The method of FIG. 1 is described with reference to FIGS. 2A-2E where appropriate.

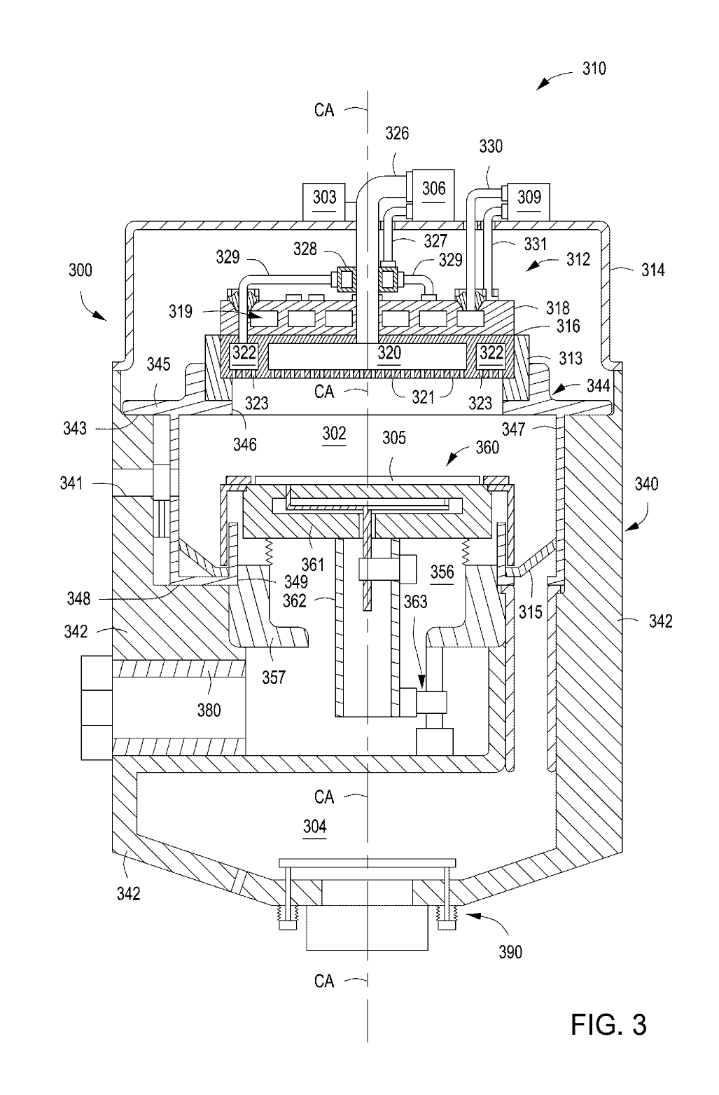

The method 100 begins at 102, as depicted in FIG. 2A, by providing a substrate 200 comprising a silicon germanium layer 202 to a substrate support in a substrate processing chamber, for example the processing chamber depicted in FIG. 3. The substrate 200 may be, for example, a doped or undoped silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 200 may be a semiconductor wafer.

The silicon germanium layer 202 may be formed using any suitable deposition process, such as chemical vapor deposition (CVD). For example, in some embodiments, the silicon germanium layer 202 is formed using a first process gas mixture including a first silicon precursor gas and a germanium precursor gas. The first silicon precursor may be utilized for depositing the silicon element of the silicon germanium layer 202. The first silicon precursor may comprise silicon, chlorine, and hydrogen. In some embodiments, the first silicon precursor includes at least one of dichlorosilane (H₂SiCl₂), trichlorosilane (HSiCl₃), silicon tetrachloride (SiCl₄), or the like. In some embodiments, the first silicon precursor comprises dichlorosilane (H₂SiCl₂). The first silicon precursor may be combined with a germanium precursor for depositing the silicon germanium layer 202. The germanium precursor may include at least one of germane (GeH₄), germanium tetrachloride (GeCl₄), silicon tetrachloride (SiCl₄), or the like. In some embodiments, the germanium precursor comprises germane (GeH₄). In some embodiments, the silicon germanium layer 202 is deposited at a pressure of about 5 to about 15 Torr. In some embodiments, the silicon germanium layer 202 is deposited at a temperature of about 700 to about 750 degrees Celsius.

The first silicon precursor and the germanium precursor may be flowed simultaneously in a first process gas mixture, and utilized to form the silicon germanium layer 202. In some embodiments, the first process gas mixture may further include a dilutant/carrier gas. The dilutant/carrier gas may include at least one of hydrogen (H₂), nitrogen (N₂), helium (He), argon (Ar), or the like. In some embodiments, the dilutant/carrier gas comprises hydrogen (H₂).

In some embodiments, and as depicted in FIG. 2A, a mask layer 204 may be formed and patterned atop the silicon germanium layer 202 to define the regions where the STI features are to be etched. The STI features to be etched in the silicon germanium layer 202 may be high aspect ratio features and/or low aspect ratio features. In some embodiments, the high aspect ratio features have a depth to width ratio of up to about 30:1. In some embodiments, the low aspect ratio features have a depth to width ratio of up to about 15:1.

The patterned mask layer 204 may be any suitable mask layer such as a hard mask or photoresist layer. For example, in embodiments where the patterned mask layer 204 is a hard mask, the patterned mask layer 204 may comprise at least one of oxides, such as silicon dioxide (SiO₂), silicon oxynitride (SiON), or the like, or nitrides, such as titanium nitride (TiN), silicon nitride (SiN), or the like, silicides, such as titanium silicide (TiSi), nickel silicide (NiSi) or the like, or silicates, such as aluminum silicate (AlSiO), zirconium silicate (ZrSiO), hafnium silicate (HfSiO), or the like. Alternatively, or in combination, in some embodiments, the patterned mask layer 204 may comprise an amorphous carbon, such as Advanced Patterning Film (APF), available from Applied Materials, Inc., located in Santa Clara, Calif., or a tri-layer resist (e.g., a photoresist layer, a Si-rich anti-reflective coating (ARC) layer, and a carbon-rich ARC, or bottom ARC (BARC) layer), a spin-on hardmask (SOH), or the like. The patterned mask layer 204 may be formed by any process suitable to form a patterned mask layer 204 capable of providing an adequate template for defining STI structures. For example, in some embodiments, the patterned mask layer 204 may be formed via a patterned etch process. In some embodiments, for example where the patterned mask layer 204 will be utilized to define advanced or very small node devices (e.g., about 40 nm or smaller nodes, such as Flash memory devices), the patterned mask layer 204 may be formed via a spacer mask patterning technique, such as a self-aligned double patterning process (SADP). In some embodiments, the patterned mask layer 204 may define one or more areas of high feature density and one or more areas of low feature density.

Next at 104, and as depicted in FIGS. 2A and 2B, the substrate 200 is exposed to a first plasma 206 formed from a first process gas to etch a feature 210 into the silicon germanium layer 202. In some embodiments, the feature 210 is etched to a depth of about 1000 angstroms to about 5000 angstroms. In some embodiments, the feature 210 is exposed to the first plasma for about 5 to about 500 seconds. For example in some embodiments, the feature 210 is exposed to the first plasma for about 10 seconds.

In some embodiments, the first process gas is a process gas suitable for etching a feature in the silicon germanium layer 202. In some embodiments, the first process gas is a chlorine containing gas. In some embodiments, the chlorine containing gas is one or more of chlorine (Cl₂), hydrogen chloride (HCl), silicon tetrachloride (SiCl₄), or the like. In some embodiments, the first process gas is a bromine containing gas such as HBr.

In some embodiments, the first process gas further comprises an inert gas, such as one of argon, helium, xenon, or the like, or a combination thereof. In some embodiments, the first process gas may be provided to the process chamber at any suitable flow rate to form the first plasma 206. For example, in some embodiments, the first process gas may be provided at a total flow rate of about 10 sccm to about 2000 sccm. For example, in some embodiments, the first process gas may consist of chlorine (Cl₂) or chlorine (Cl₂) and an inert gas. In some embodiments, the chlorine (Cl₂) or chlorine (Cl₂) and inert gas may be provided at a total flow rate of about 150 sccm. In some embodiments, the flow rate ratio of the chlorine containing gas to the inert gas is about 1 to about 200. In some embodiments, the first process gas may further include an oxygen containing gas and/or nitrogen gas (N₂). The oxygen containing gas and/or nitrogen gas at least partially oxidize and/or nitride a sidewall 214 of the feature 210, thereby reducing a lateral etch of the silicon germanium layer 202 and providing a uniform feature profile. Examples of suitable oxygen containing gases include oxygen (O₂) gas, carbon monoxide (CO), carbonyl sulfide (COS), sulfur dioxide (SO₂), or the like.

In some embodiments, the first plasma 206 may be formed by coupling RF source power at a suitable frequency to the first process gas within a suitable process chamber, such as described below with respect to FIG. 3, under suitable conditions to establish and maintain the plasma. For example, in some embodiments, about 400 watts to about 1000 watts of RF energy at a frequency in a range from about 10 to about 50 kHz, having continuous wave or pulsing capabilities, may be provided to the process chamber to ignite and maintain the plasma. For example, in some embodiments, the RF source power may be provided at about 700 watts. In some embodiments, the source power may be pulsed during the etching cycle. To pulse the source power, the radio frequency power is switched on and off during the etching cycle. In some embodiments, the switching of the power on and off is uniformly distributed in time throughout the etching cycle. In some embodiments, the timing profile of the pulsing may be varied throughout the etching cycle, and may depend on the composition of the substrate. The percentage of time the source power is switched on, i.e. the duty cycle as described above, is directly related to the pulsing frequency. In some embodiments, when the pulsing frequency ranges from about 10 to about 50 kHz, the duty cycle ranges from about 1% to about 99%. The source power frequency and the pulsing frequency may be adjusted depending on the substrate material being processed. In one example, the RF source power may be provided at a 50 Hz pulse frequency and a 20% duty cycle.

In some embodiments, about 30 watts to about 400 watts of a bias power may be provided, for example, an RF bias power at a frequency of about 10 to about 50 kHz may be provided to the substrate via a substrate support. For example, in some embodiments, RF bias power of 400 watts at 2 MHz may be provided to the substrate. The bias power may be pulsed during the etching cycle. To pulse the bias power, the radio frequency power is switched on and off during the etching cycle. In some embodiments, the switching of the power on and off is uniformly distributed in time throughout the etching cycle. In some embodiments, the timing profile of the pulsing may be varied throughout the etching cycle, and may depend on the composition of the substrate. The percentage of time the bias power is switched on, i.e. the duty cycle as described above, is directly related to the pulsing frequency. In some embodiments, when the pulsing frequency ranges from about 10 to about 50 kHz, the duty cycle ranges from about 1% to about 99%. The bias power frequency and the pulsing frequency may be adjusted depending on the substrate material being processed.

In some embodiments, the process chamber may be maintained at a pressure of about 5 mTorr to about 10 mTorr. In some embodiments, the process chamber may be maintained at a temperature of about −10 degrees Celsius to about 250 degrees Celsius during etching.

Next at 106, and as depicted in FIGS. 2B and 2C, the substrate 200 is exposed to a second plasma 208 formed from a second process gas to oxidize a bottom 212 and sidewalls 214 of the feature 210. The presence of the oxide layer 218 prevents damage to the sidewalls 214 of the feature 210 as the feature 210 is further etched to a desired depth. In some embodiments, the second plasma 208 is formed from a second process gas comprising an oxygen-containing gas suitable for oxidizing the bottom 212 and sidewalls 214 of the feature 210. In some embodiments, the oxygen-containing gas can be for example, a gas that contains oxygen or oxygen and other essentially non-reactive elements, such as nitrogen, or the like. For example, in some embodiments, the oxygen containing gas may be, for example, one or more of oxygen gas (O₂), ozone (O₃), nitrous oxide (N₂O), or the like. In some embodiments, the second process gas further comprises an inert gas such as argon, helium, or the like. In some embodiments, the second process gas may be provided to the process chamber at any suitable flow rate to form the second plasma 208. For example, in some embodiments, the second process gas may be provided at a flow rate of about 10 sccm to about 1000 sccm. In some embodiments, the flow rate ratio of the oxygen containing gas to the inert gas is about 1 to about 200. For example in some embodiments, the second process gas may comprise oxygen, or oxygen and nitrogen, or oxygen and at least one of nitrogen or an inert gas, or oxygen. For example, in some embodiments, the second process gas may consist of oxygen (O₂) and nitrogen (N₂). In some embodiments, the second process gas may consist of oxygen (O₂) provided at about 200 sccm and nitrogen (N₂) provided at about 100 sccm.

In some embodiments, the second plasma 208 may be formed in the same process chamber as the first plasma. In some embodiments, the second plasma 208 may be formed by coupling RF power at a suitable frequency to the second process gas within a suitable process chamber, such as described below with respect to FIG. 3, under suitable conditions to establish and maintain the plasma. For example, in some embodiments, about 400 watts to about 1000 watts of RF energy at a frequency in a range from about 10 Hz to about 50 kHz may be provided to the process chamber to ignite and maintain the plasma. For example, in some embodiments, RF power may be provided at about 1000 watts. In some embodiments, the process chamber may be maintained at a pressure of about 5 mTorr to about 10 mTorr. In some embodiments, the process chamber is maintained at 10 mTorr. In some embodiments, the process chamber may be maintained at a temperature of about −10 degrees Celsius to about 250 degrees Celsius during oxidation.

Next at 108, and as depicted in FIGS. 2C and 2D, the oxide layer 218 is exposed to a third plasma 216 formed from a third process gas to etch the oxide layer 218 from the bottom 212 of the feature 210. The third plasma 216 is formed from any suitable process gas used to etch an oxide layer with appropriate selectivity against surrounding layers that are not to be etched. For example, in some embodiments, a third process gas may comprise a halogen-containing gas. For example, in some embodiments, the third plasma 216 is formed from a third process gas comprising a fluorine containing gas, for example one or more of tetrafluoromethane (CF₄), hexafluoroethane (C₂F₆), fluoromethane (CH₃F), difluoromethane (CH₂F₂), methyl trifluoride (CHF₃), hexafluorobutadiene (C₄F₆), and octafluorocyclobutane (C₄F₈). In some embodiments, the third process gas further comprises an inert gas such as argon, helium, or the like. In some embodiments, the third process gas may be provided to the process chamber at any suitable flow rate to form the third plasma 216. For example, in some embodiments, the third process gas may be provided at a flow rate of about 10 sccm to about 1000 sccm. For example, in some embodiments, the third process gas may consist of methyl trifluoride (CHF₃) provided at about 100 sccm and argon (Ar) provided at about 200 sccm.

In some embodiments, the third plasma 216 may be formed in the same process chamber as the first plasma 206 and the second plasma 208. In some embodiments, the third plasma 216 may be formed by coupling RF power at a suitable frequency to the third process gas within a suitable process chamber, such as described below with respect to FIG. 3, under suitable conditions to establish and maintain the plasma. For example, in some embodiments, about 400 watts to about 1000 watts of RF energy at a frequency in a range from about 10 Hz to about 50 kHz may be provided to the process chamber to ignite and maintain the plasma. For example, in some embodiments, RF power may be provided at about 300 watts to about 400 watts. In some embodiments, about 30 watts to about 150 watts of a bias power may be provided, for example, an RF bias power at a frequency of about 10 to about 50 kHz, to the substrate via a substrate support. For example, in some embodiments, RF bias power of 30 watts at 2 MHz may be provided to the substrate. In some embodiments, the process chamber may be maintained at a pressure of about 5 mTorr to about 10 mTorr. In some embodiments, the process chamber is maintained at 10 mTorr. In some embodiments, the process chamber may be maintained at a temperature of about −10 degrees Celsius to about 250 degrees Celsius during etching of the oxide layer.

Next, at 110, as depicted in FIG. 2E, 104-108 can be repeated to form the feature 210 to a desired depth. For example, a first cycle may consist of: etching the silicon germanium layer for a first period of time using a first plasma 206 formed by applying RF power to ignite a first process gas provided to the process chamber at a first flow rate, while applying a bias power to the substrate; subsequently oxidizing the bottom 212 and sidewalls 214 of the feature 210 by exposing the substrate 200, for a second period of time, to a second plasma 208 formed by applying RF power to ignite a second process gas, provided to the process chamber at a second flow rate; subsequently the oxide layer 218 from the bottom 212 of the feature 210 is etched for a third period of time using a third plasma 216 formed by applying RF power to ignite a third process gas, while applying a bias power to the substrate. In some embodiments, each of 104-108 are performed in a single process chamber. In some embodiments, the substrate may be transferred to different process chambers to perform some or all of 104-108.

For example, a first cycle may consist of: etching the silicon germanium layer for about 10 seconds at a chamber pressure of 10 mTorr using a first plasma 206 formed by applying RF power at 700 watts to ignite a first process gas consisting of chlorine (Cl₂) provided to the process chamber at about 150 sccm, while applying a bias power of about 400 watts at a frequency of 2 MHz to the substrate; subsequently oxidizing the bottom 212 and sidewalls 214 of the feature 210 by exposing the substrate 200, for about 9 seconds at a chamber pressure of about 10 mTorr, to a second plasma 208 formed by applying RF power at 1000 watts to ignite a second process gas consisting of oxygen (O₂), provided to the process chamber at 200 sccm, and nitrogen (N₂), provided to the process chamber at 100 sccm; subsequently the oxide layer 218 from the bottom 212 of the feature 210 is etched for about 9 seconds at a chamber pressure of 10 mTorr using a third plasma 216 formed by applying RF power at 1000 watts to ignite a third process gas consisting of methyl trifluoride (CHF₃), provided to the process chamber at about 100 sccm, and argon (Ar), provided to the process chamber at 200 sccm, while applying a bias power of about 30 watts at a frequency of about 2 MHz to the substrate. A feature 210 having a depth of about 1000 angstroms to about 5000 angstroms may be formed in the silicon germanium layer 202 by repeating this cycle for about 2 to about 100 cycles.

Once the desired depth is reached the method 100 generally ends and the substrate 200 may continue to be processed as desired. For example, in some embodiments, the substrate may subsequently undergo a cleaning process, for example using sulfuric acid (H₂SO₄) to remove unwanted etching by-products from the substrate and additional fabrication processes may be performed to complete the desired structures and devices on the substrate.

FIG. 3 depicts a schematic diagram of an illustrative plasma process chamber 300 of the kind that may be used to practice embodiments of the invention as discussed herein. The plasma process chamber 300 may be utilized alone or, more typically, as a processing module of an integrated semiconductor substrate processing system, or cluster tool, such as a CENTURA® integrated semiconductor substrate processing system, available from Applied Materials, Inc. of Santa Clara, Calif.

The plasma processing chamber 300 may be a plasma etch chamber, a plasma enhanced chemical vapor deposition chamber, a physical vapor deposition chamber, a plasma treatment chamber, an ion implantation chamber, or other suitable vacuum processing chamber. The plasma processing chamber 300 generally includes a chamber lid assembly 310, a chamber body assembly 340, and an exhaust assembly 390, which collectively enclose a processing region 302 and an evacuation region 304. In practice, processing gases are introduced into the processing region 302 and ignited into a plasma using RF power. A substrate 305 is positioned on a substrate support assembly 360 and exposed to the plasma generated in the processing region 302 to perform a plasma process on the substrate 305, such as etching, chemical vapor deposition, physical vapor deposition, implantation, plasma annealing, plasma treating, abatement, or other plasma processes. Vacuum is maintained in the processing region 302 by the exhaust assembly 390, which removes spent processing gases and byproducts from the plasma process through the evacuation region 304.

The chamber lid assembly 310 generally includes an upper electrode 312 (or anode) isolated from and supported by the chamber body assembly 340 and a chamber lid 314 enclosing the upper electrode 312. The upper electrode 312 is coupled to an RF power source 303 via a conductive gas inlet tube 326. The conductive gas inlet tube 326 is coaxial with a central axis (CA) of the chamber body assembly 340 so that both RF power and processing gases are symmetrically provided. The upper electrode 312 includes a showerhead plate 316 attached to a heat transfer plate 318.

The showerhead plate 316 has a central manifold 320 and one or more outer manifolds 322. The one or more outer manifolds 322 circumscribe the central manifold 320. The central manifold 320 receives processing gases from a gas source 306 through the gas inlet tube 326 and distributes the received processing gases into a central portion of the processing region 302 through a plurality of gas passages 321. The outer manifold(s) 322 receives processing gases, which may be the same or a different mixture of gases received in the central manifold 320, from the gas source 306. The outer manifold(s) 322 then distributes the received processing gases into an outer portion of the processing region 302 through a plurality of gas passages 323. The manifolds 320, 322 have sufficient volume to function as a plenum so that uniform pressure is provided to each gas passage 321 associated with a respective manifold 320, 322.

A processing gas from the gas source 306 is delivered through an inlet tube 327 into a ring manifold 328 concentrically disposed around the gas inlet tube 326. From the ring manifold 328, the processing gas is delivered through a plurality of gas tubes 329 to the outer manifold(s) 322. In one embodiment, the ring manifold 328 includes a recursive gas path to assure that gas flows equally from the ring manifold 328 into the gas tubes 329.

A heat transfer fluid is delivered from a fluid source 309 to the heat transfer plate 318 through a fluid inlet tube 330. The fluid is circulated through one or more fluid channels 319 disposed in the heat transfer plate 318 and returned to the fluid source 309 via a fluid outlet tube 331.

The chamber body assembly 340 includes a chamber body 342. The substrate support assembly 360 is centrally disposed within the chamber body 342 and positioned to support the substrate 305 in the processing region 302 symmetrically about the central axis (CA).

An upper liner assembly 344 is disposed within an upper portion of the chamber body 342 circumscribing the processing region 302. The upper liner assembly 344 shields the upper portion of the chamber body 342 from the plasma in the processing region 302 and is removable to allow periodic cleaning and maintenance. In one embodiment, the upper liner assembly 344 is temperature controlled, such as by an AC heater (not shown) in order to enhance the thermal symmetry within the chamber and symmetry of the plasma provided in the processing region 302.

The chamber body 342 includes a ledge 343 that supports an outer flange 345 of the upper liner assembly 344. An inner flange 346 of the upper liner assembly 344 supports the upper electrode 312. An insulator 313 is positioned between the upper liner assembly 344 and the upper electrode 312 to provide electrical insulation between the chamber body assembly 340 and the upper electrode 312.

The upper liner assembly 344 includes an outer wall 347 attached to the inner and outer flanges (346,345), a bottom wall 348, and an inner wall 349. The outer wall 347 and inner wall 349 are substantially vertical, cylindrical walls. The outer wall 347 is positioned to shield chamber body 342 from plasma in the processing region 302, and the inner wall 349 is positioned to at least partially shield the side of the substrate support assembly 360 from plasma in the processing region 302. The bottom wall 348 joins the inner and outer walls (349, 347).

The processing region 302 is accessed through a slit valve tunnel 341 disposed in the chamber body 342 that allows entry and removal of the substrate 305 into/from the substrate support assembly 360. The upper liner assembly 344 has a slot 350 disposed therethrough that matches the slit valve tunnel 341 to allow passage of the substrate 305 therethrough.

The substrate support assembly 360 generally includes lower electrode 361 (or cathode) and a hollow pedestal 362, the center of which the central axis (CA) passes through, and is supported by a central support member 357 disposed in the central region 356 and supported by the chamber body 342. The central axis (CA) also passes through the center of the central support member 357. The lower electrode 361 is coupled to the RF power source 303 through a matching network (not shown) and a cable (not shown) routed through the hollow pedestal 362. When RF power is supplied to the upper electrode 312 and the lower electrode 361, an electrical field formed therebetween ignites the processing gases present in the processing region 302 into a plasma.

The central region 356 is sealed from the processing region 302 and may be maintained at atmospheric pressure, while the processing region 302 is maintained at vacuum conditions.

An actuation assembly 363 is positioned within the central region 356 and attached to the chamber body 342 and/or the central support member 357 to raises or lowers the pedestal 362. Since the lower electrode 361 is supported by the pedestal 362, the actuation assembly 363 provides vertical movement of the lower electrode 361 relative to the chamber body 342, the central support member 357, and the upper electrode 312. In addition, since the substrate 305 is supported by the lower electrode 361, the gap between the substrate 305 and the showerhead plate 316 may also be varied, resulting in greater control of the process gas distribution across the substrate 305.

In one embodiment, the lower electrode 361 is an electrostatic chuck, and thus includes one or more electrodes (not shown) disposed therein. A voltage source (not shown) biases the one or more electrodes with respect to the substrate 305 to create an attraction force to hold the substrate 305 in position during processing. Cabling coupling the one or more electrodes to the voltage source is routed through the hollow pedestal 362 and out of the chamber body 342 through one of the plurality of access tubes 380.

A conductive, slant mesh liner 315 is positioned in a lower portion of the upper liner assembly 344. The slant mesh liner 315 may have a plurality of apertures formed there through to allow exhaust gases to be drawn uniformly therethrough, which in turn, facilitates uniform plasma formation in the processing region 302 and allows greater control of the plasma density and gas flow in the processing region 302.

The invention may be practiced using other semiconductor substrate processing systems wherein the processing parameters may be adjusted to achieve acceptable characteristics by those skilled in the art by utilizing the teachings disclosed herein without departing from the spirit of the invention.

While the foregoing is directed to embodiments of the present invention, other and further embodiments of the invention may be devised without departing from the basic scope thereof.

1. A method of processing a substrate, comprising:
(a) providing a substrate to a substrate support in a process chamber, wherein the substrate comprises a silicon germanium (SiGe) layer and a patterned mask layer atop the silicon germanium layer to define a feature in the silicon germanium layer;
(b) exposing the substrate to a first plasma formed from a first process gas to etch a feature into the silicon germanium layer;
(c) subsequently exposing the substrate to a second plasma formed from a second process gas to form an oxide layer on a sidewall and a bottom of the feature;
(d) exposing the substrate to a third plasma formed from a third process gas to etch the oxide layer from the bottom of the feature; and
(e) repeating (b)-(d) to form the feature in the silicon germanium layer to a desired depth, wherein the first process gas, the second process gas, and the third process gas are not the same.

2. The method of claim 1, wherein the first process gas comprises a chlorine containing gas.

3. The method of claim 2, wherein the chlorine containing gas comprises one or more of chlorine (Cl₂), hydrogen chloride (HCl), or silicon tetrachloride (SiCl₄).

4. The method of claim 1, wherein the second process gas comprises an oxygen containing gas.

5. The method of claim 4, wherein the second process gas further nitrogen.

6. The method of claim 4, wherein the oxygen containing gas comprises one or more of oxygen gas (O₂), ozone (O₃), or nitrous oxide (N₂O).

7. The method of claim 1, wherein the third process gas comprises a fluorine containing gas.

8. The method of claim 7, wherein the fluorine containing gas comprises one or more of tetrafluoromethane (CF₄), hexafluoroethane (C₂F₆), fluoromethane (CH₃F), difluoromethane (CH₂F₂), methyl trifluoride (CHF₃), hexafluorobutadiene (C₄F₆), and octafluorocyclobutane (C₄F₈).

9. The method of claim 1, wherein the first plasma, the second plasma, and the third plasma is formed using an RF power source.

10. The method of claim 9, wherein the RF power source provides power at about 400 watts to about 1000 watts.

11. The method of claim 1, further comprising applying a bias power to the substrate of about 30 watts to about 400 watts during (a) and (d).

12. The method of claim 11, further comprising applying a bias power to the substrate at a frequency of about 2 MHz during (a) and (d).

13. The method of claim 1, wherein the first process gas, the second process gas, and the third process gas further comprise an inert gas.

14. The method of claim 1, wherein the first process gas, the second process gas and the third process gas is supplied to the process chamber at about 100 sccm to about 200 sccm.

15. The method of claim 1, wherein a pressure within the process chamber during (b)-(d) is about 5 to about 10 mTorr.

16. The method of claim 1, wherein (b)-(d) are performed for about 6 to about 10 seconds each.

17. The method of claim 1, wherein (a)-(e) are performed in a single process chamber.

18. A method of processing a substrate, comprising:
(a) exposing the substrate, comprising a silicon germanium layer and a patterned mask layer disposed atop the silicon germanium layer, to a first plasma formed from a chlorine containing gas to etch a feature into the silicon germanium layer, wherein the feature comprises sidewalls and a bottom;
(b) subsequently exposing the substrate to a second plasma formed from an oxygen containing gas to form an oxide layer on the sidewalls and bottom of the feature;
(c) subsequently exposing the substrate to a third plasma formed from a fluorine containing gas to etch the oxide layer from the bottom of the feature;
(d) applying a bias power to the substrate of about 30 watts to about 400 watts during (a) and (c) and at a frequency of about 2 MHz; and
(e) repeating (a)-(d) to form the feature in the silicon germanium layer to a desired depth.

19. A non-transitory computer readable medium having instructions stored thereon that, when executed, cause a method of processing a substrate, the method comprising:
(a) providing a substrate to a substrate support in a process chamber, wherein the substrate comprises a silicon germanium (SiGe) layer and a patterned mask layer atop the silicon germanium layer to define a feature in the silicon germanium layer;
(b) exposing the substrate to a first plasma formed from a first process gas to etch a feature into the silicon germanium layer, wherein the feature comprises sidewalls and a bottom;
(c) subsequently exposing the substrate to a second plasma formed from a second process gas to form an oxide layer on the sidewalls and bottom of the feature;
(d) exposing the substrate to a third plasma formed from a third process gas to etch the oxide layer from the bottom of the feature; and
(e) repeating (b)-(d) to form the feature in the silicon germanium layer to a desired depth, wherein the first process gas, the second process gas and the third process gas are not the same.

20. The non-transitory computer readable medium of claim 19, wherein the first process gas comprises a chlorine containing gas, the second process gas comprises an oxygen containing gas, and the third process gas comprises a fluorine containing gas.
